(19) United States
(12) Patent Application Publication
(10) Pub. No.: US 2026/0123533 A1
(43) Pub. Date: Apr. 30, 2026

(54) SEMICONDUCTOR DEVICE STACK STRUCTURE

(71) Applicant: Powerchip Semiconductor Manufacturing Corporation, Hsinchu (TW)

(72) Inventors: Shou-Zen Chang, Hsinchu City (TW); Chun-Lin Lu, Hsinchu City (TW); Yung Nien Koh, Hsinchu (TW)

(73) Assignee: Powerchip Semiconductor Manufacturing Corporation, Hsinchu (TW)

(21) Appl. No.: 18/964,709

(22) Filed: Dec. 2, 2024

(30) Foreign Application Priority Data
Oct. 29, 2024 (TW) 113141210

(51) Int. Cl. H01L 25/065; H01L 23/00; H01L 23/48; H01L 23/528

(52) U.S. Cl. CPC H10W 90/00; H10W 20/20; H10W 20/435; H10W 90/297; H10W 90/722; H10W 90/792

(57) ABSTRACT

A semiconductor device stack structure including first semiconductor device structures arranged in a stack is provided. Each of the first semiconductor device structures includes a substrate, semiconductor devices, a redistribution layer (RDL), a first through-substrate via (TSV), and second TSVs. The substrate has a front side and a back side. The semiconductor devices are located on the front side of the substrate. The RDL is located on the back side of the substrate. The first TSV passes through the substrate. The first TSV is electrically connected to the RDL. The second TSVs pass through the substrate. Each of the second TSVs is located directly below the corresponding semiconductor device. Each of the second TSVs is electrically connected to the corresponding semiconductor device and the RDL. The size of the first TSV is greater than the size of each of the second TSVs.

### CROSS-REFERENCE TO RELATED APPLICATION

This application claims the priority benefit of Taiwan application serial no. 113141210, filed on October 29, 2024. The entirety of the above-mentioned patent application is hereby incorporated by reference herein and made a part of this specification.

### BACKGROUND

### Technical Field

The disclosure relates to a semiconductor structure, and particularly relates to a semiconductor device stack structure.

### Description of Related Art

In wafer stack structures or chip stack structures, the number of routing layers on the front side of the substrate is continuously increasing, which increases the complexity of circuit design. Additionally, wafer stack structures or chip stack structures often rely on through-substrate vias (TSVs) to achieve power supply and/or signal transmission. Therefore, how to reduce the footprint occupied by through-substrate vias is an issue that deserves more attention and efforts.

### SUMMARY

The disclosure provides a semiconductor device stack structure, which reduces the number of routing layers on the front side of the substrate and the footprint occupied by through-substrate vias.

An embodiment of the disclosure provides a semiconductor device stack structure, which includes multiple first semiconductor device structures arranged in a stack. Each of the first semiconductor device structures includes a substrate, multiple semiconductor devices, a redistribution layer (RDL), a first through-substrate via, and multiple second through-substrate vias. The substrate has a front side and a back side. The semiconductor devices are located on the front side of the substrate. The redistribution layer is located on the back side of the substrate. The first through-substrate via passes through the substrate. The first through-substrate via is electrically connected to the redistribution layer. The second through-substrate vias pass through the substrate. Each of the second through-substrate vias is located directly below the corresponding semiconductor device. Each of the second through-substrate vias is electrically connected to the corresponding semiconductor device and the redistribution layer. A size of the first through-substrate via is greater than a size of each of the second through-substrate vias.

According to an embodiment of the disclosure, in the semiconductor device stack structure, the first semiconductor device structures are multiple semiconductor wafers.

According to an embodiment of the disclosure, in the semiconductor device stack structure, the first semiconductor device structures are multiple semiconductor chips.

According to an embodiment of the disclosure, in the semiconductor device stack structure, the first through-substrate via is not located directly below the semiconductor devices.

According to an embodiment of the disclosure, in the semiconductor device stack structure, an overall height of the first through-substrate via is greater than an overall height of each of the second through-substrate vias.

According to an embodiment of the disclosure, in the semiconductor device stack structure, a volume of the first through-substrate via is greater than a volume of each of the second through-substrate vias.

According to an embodiment of the disclosure, in the semiconductor device stack structure, a volume of the first through-substrate via is 10 times to 1000 times a volume of each of the second through-substrate vias.

According to an embodiment of the disclosure, in the semiconductor device stack structure, each of the first semiconductor device structures further includes a dielectric structure. The dielectric structure is located on the front side of the substrate. The semiconductor devices are located in the dielectric structure.

According to an embodiment of the disclosure, in the semiconductor device stack structure, the first through-substrate via extends into the dielectric structure.

According to an embodiment of the disclosure, in the semiconductor device stack structure, each of the first semiconductor device structures further includes a dielectric structure. The dielectric structure is located on the back side of the substrate. The redistribution layer is located in the dielectric structure.

According to an embodiment of the disclosure, in the semiconductor device stack structure, the first through-substrate via and the second through-substrate vias extend into the dielectric structure.

According to an embodiment of the disclosure, in the semiconductor device stack structure, two adjacent first semiconductor device structures are bonded to each other.

According to an embodiment of the disclosure, in the semiconductor device stack structure, a bonding method for bonding two adjacent first semiconductor device structures includes bump bonding.

According to an embodiment of the disclosure, in the semiconductor device stack structure, a bonding method for bonding two adjacent first semiconductor device structures includes hybrid bonding.

According to an embodiment of the disclosure, the semiconductor device stack structure includes multiple first through-substrate vias and multiple redistribution layers. Each first through-substrate via is electrically connected to the corresponding redistribution layer.

According to an embodiment of the disclosure, in the semiconductor device stack structure, the first through-substrate vias are located between the second through-substrate vias.

According to an embodiment of the disclosure, the semiconductor device stack structure further includes a second semiconductor device structure. The first semiconductor device structures are stacked on the second semiconductor device structure.

According to an embodiment of the disclosure, in the semiconductor device stack structure, the second semiconductor device structure is a semiconductor wafer.

According to an embodiment of the disclosure, in the semiconductor device stack structure, the second semiconductor device structure is a semiconductor chip.

According to an embodiment of the disclosure, in the semiconductor device stack structure, one of the first semiconductor device structures that is closest to the second semiconductor device structure is bonded to the second semiconductor device structure.

Based on the above, in the semiconductor device stack structure according to the disclosure, multiple second through-substrate vias pass through the substrate. Each second through-substrate via is located directly below the corresponding semiconductor device. Each second through-substrate via is electrically connected to the corresponding semiconductor device and the redistribution layer. The size of the first through-substrate via is greater than the size of each second through-substrate via. That is, the second through-substrate via may be smaller in size. Therefore, the number of routing layers on the front side of the substrate and the footprint occupied by the through-substrate vias can be reduced, which increases the flexibility in controlling warpage of the wafer/chip. Moreover, power supply and/or signal transmission to the semiconductor devices can be achieved by the second through-substrate vias and the redistribution layer on the back side of the substrate.

To make the foregoing features and advantages of the disclosure more understandable, exemplary embodiments are described in detail below with reference to the accompanying drawings.

### BRIEF DESCRIPTION OF THE DRAWINGS

FIG. 1 is a cross-sectional view of the semiconductor device stack structure according to some embodiments of the disclosure.

FIG. 2 is a cross-sectional view of the semiconductor device stack structure according to other embodiments of the disclosure.

### DESCRIPTION OF THE EMBODIMENTS

Exemplary embodiments will be described in detail below with reference to the accompanying drawings, but the provided embodiments are not intended to limit the scope of the disclosure. For ease of understanding, identical components are denoted by the same reference numerals in the following description. Moreover, the accompanying drawings are for illustrative purposes only, and may not be drawn to scale. In fact, the dimensions of various features may be arbitrarily increased or reduced for clarity.

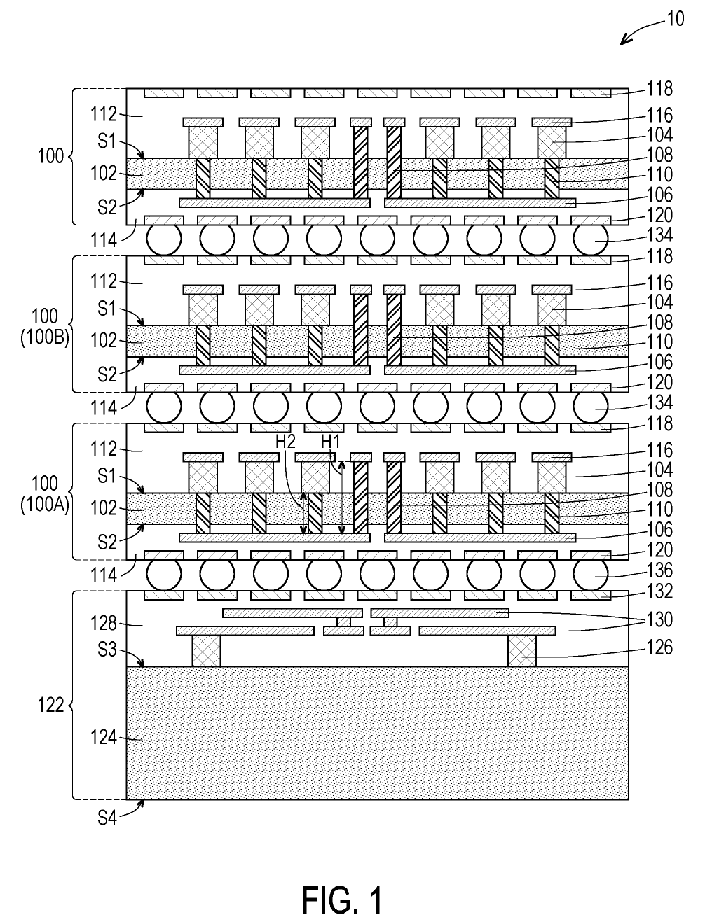

FIG. 1 is a cross-sectional view of the semiconductor device stack structure according to some embodiments of the disclosure.

Referring to FIG. 1, a semiconductor device stack structure 10 includes multiple semiconductor device structures 100 arranged in a stack. Nevertheless, the number of the semiconductor device structures 100 is not limited to the number shown in the drawing, and any number more than one falls within the scope of the disclosure. In some embodiments, the multiple semiconductor device structures 100 may be multiple semiconductor wafers or multiple semiconductor chips. Each semiconductor device structure 100 includes a substrate 102, multiple semiconductor devices 104, a redistribution layer 106, a through-substrate via 108, and multiple through-substrate vias 110. Furthermore, the number of the semiconductor devices 104 and the number of the through-substrate vias 110 are not limited to the numbers shown in the drawing, and any number more than one falls within the scope of the disclosure. The substrate 102 has a front side S1 and a back side S2. In some embodiments, the substrate 102 may be a semiconductor substrate such as a silicon substrate.

The semiconductor devices 104 are located on the front side S1 of the substrate 102. In some embodiments, the semiconductor devices 104 may be active devices, passive devices, or a combination thereof. In some embodiments, the semiconductor devices 104 may be memories (for example, dynamic random access memory (DRAM)), transistors, capacitors, resistors, or a combination thereof. In some embodiments, the semiconductor devices 104 in the same semiconductor device structure 100 may be identical devices or different devices. In some embodiments, the semiconductor devices 104 in different semiconductor device structures 100 may be identical devices or different devices. In some embodiments, the layout designs of the semiconductor devices 104 in different semiconductor device structures 100 may be identical or different. In this embodiment, the layout design of the semiconductor devices 104 in the semiconductor device structure 100A may be identical to the layout design of the semiconductor devices 104 in the semiconductor device structure 100B, but the disclosure is not limited thereto. In other embodiments, the layout design of the semiconductor devices 104 in the semiconductor device structure 100A may be different from the layout design of the semiconductor devices 104 in the semiconductor device structure 100B.

In some embodiments, each semiconductor device structure 100 may further include a dielectric structure 112. The dielectric structure 112 is located on the front side S1 of the substrate 102. The semiconductor devices 104 are located in the dielectric structure 112. In some embodiments, the material of the dielectric structure 112 may be, for example, silicon oxide, silicon nitride, or a combination thereof.

The redistribution layer 106 is located on the back side S2 of the substrate 102. The redistribution layer 106 may be a single-layer structure or a multi-layer structure. In some embodiments, the material of the redistribution layer 106 may be, for example, copper, tantalum, tantalum nitride, or a combination thereof.

In some embodiments, each semiconductor device structure 100 may further include a dielectric structure 114. The dielectric structure 114 is located on the back side S2 of the substrate 102. The redistribution layer 106 is located in the dielectric structure 114. In some embodiments, the material of the dielectric structure 114 may be, for example, silicon oxide, silicon nitride, or a combination thereof.

The through-substrate via 108 passes through the substrate 102. The through-substrate via 108 is electrically connected to the redistribution layer 106. In some embodiments, the semiconductor device stack structure 10 may include multiple through-substrate vias 108 and multiple redistribution layers 106. Each through-substrate via 108 may be electrically connected to the corresponding redistribution layer 106. In some embodiments, the through-substrate via 108 is not located directly below the semiconductor devices 104. In some embodiments, the through-substrate via 108 may extend into the dielectric structure 112. In some embodiments, the through-substrate via 108 may extend into the dielectric structure 114. In some embodiments, the material of the through-substrate via 108 may be, for example, copper, tantalum, tantalum nitride, or a combination thereof.

The through-substrate vias 110 pass through the substrate 102. Each through-substrate via 110 is located directly below the corresponding semiconductor device 104. Each through-substrate via 110 is electrically connected to the corresponding semiconductor device 104 and the redistribution layer 106. In some embodiments, the through-substrate via 110 may be directly connected to an electrode (not shown) in the semiconductor device 104. In some embodiments, the through-substrate via 110 may be electrically connected to the semiconductor device 104 by an interconnection structure (not shown). In some embodiments, the through-substrate vias 110 may extend into the dielectric structure 114. In some embodiments, the through-substrate vias 108 may be located between the through-substrate vias 110. In some embodiments, the material of the through-substrate via 110 may be, for example, copper, tantalum, tantalum nitride, or a combination thereof.

The size of the through-substrate via 108 is greater than the size of each through-substrate via 110. In some embodiments, the overall height H1 of the through-substrate via 108 may be greater than the overall height H2 of each through-substrate via 110. In some embodiments, the volume of the through-substrate via 108 may be greater than the volume of each through-substrate via 110. In some embodiments, the volume of the through-substrate via 108 may be 10 times to 1000 times the volume of each through-substrate via 110.

In some embodiments, each semiconductor device structure 100 may further include multiple interconnection structures 116, multiple pads 118, and multiple pads 120. Each interconnection structure 116 is electrically connected to the corresponding through-substrate via 108 or the corresponding semiconductor device 104. In some embodiments, the material of the interconnection structure 116 may be, for example, copper, aluminum, tungsten, tantalum, tantalum nitride, titanium, titanium nitride, or a combination thereof. The pads 118 are located in the dielectric structure 112. In some embodiments, the interconnection structure 116 may be electrically connected to the corresponding pad 118 by other interconnection structures (not shown). In some embodiments, the material of the pad 118 may be, for example, a conductive material such as aluminum. The pads 120 are located in the dielectric structure 114. The redistribution layer 106 may be electrically connected to the corresponding pad 120 by an interconnection structure (not shown). In some embodiments, the material of the pad 120 may be, for example, a conductive material such as aluminum.

In some embodiments, the semiconductor device stack structure 10 may further include a semiconductor device structure 122. The semiconductor device structures 100 may be stacked on the semiconductor device structure 122. In some embodiments, the semiconductor device structure 122 may be a semiconductor wafer or a semiconductor chip.

The semiconductor device structure 122 includes a substrate 124, multiple semiconductor devices 126, a dielectric structure 128, multiple interconnection structures 130, and multiple pads 132. The substrate 124 has a front side S3 and a back side S4. In some embodiments, the substrate 124 may be a semiconductor substrate such as a silicon substrate.

The semiconductor devices 126 are located on the front side S3 of the substrate 124. In some embodiments, the semiconductor devices 126 may be active devices, passive devices, or a combination thereof. In some embodiments, the semiconductor devices 126 may be memories (for example, dynamic random access memory), transistors, capacitors, resistors, or a combination thereof. In some embodiments, the semiconductor devices 126 in the semiconductor device structure 122 may be identical or different devices.

The dielectric structure 128 is located on the front side S3 of the substrate 124. The semiconductor devices 126 may be located in the dielectric structure 128. In some embodiments, the material of the dielectric structure 128 may be, for example, silicon oxide, silicon nitride, or a combination thereof.

The interconnection structures 130 are located in the dielectric structure 128. The semiconductor device 126 may be electrically connected to the corresponding interconnection structure 130. In some embodiments, the material of the interconnection structure 130 may be, for example, copper, aluminum, tungsten, tantalum, tantalum nitride, titanium, titanium nitride, or a combination thereof.

The pads 132 are located in the dielectric structure 128. The interconnection structure 130 may be electrically connected to the corresponding pad 132 by other interconnection structures (not shown). In some embodiments, the material of the pad 132 may be, for example, a conductive material such as aluminum.

In some embodiments, two adjacent semiconductor device structures 100 may be bonded to each other. In this embodiment, the bonding method for bonding two adjacent semiconductor device structures 100 may be bump bonding, but the disclosure is not limited thereto. In some embodiments, the semiconductor device stack structure 10 may further include a connection terminal 134. For example, the connection terminal 134 is located between the pad 118 of one of two adjacent semiconductor device structures 100 (for example, semiconductor device structure 100A) and the pad 120 of the other of two adjacent semiconductor device structures 100 (for example, semiconductor device structure 100B), and is electrically connected to the pad 118 of one of two adjacent semiconductor device structures 100 (for example, semiconductor device structure 100A) and the pad 120 of the other of two adjacent semiconductor device structures 100 (for example, semiconductor device structure 100B), thereby bonding the two adjacent semiconductor device structures 100 to each other. In some embodiments, the connection terminal 134 may be a bump (for example, solder ball), but the disclosure is not limited thereto.

In some embodiments, one of the semiconductor device structures 100 that is closest to the semiconductor device structure 122 may be bonded to the semiconductor device structure 122. For example, the semiconductor device structure 100A may be bonded to the semiconductor device structure 122. In this embodiment, the bonding method for bonding the semiconductor device structure 100A and the semiconductor device structure 122 may be bump bonding, but the disclosure is not limited thereto. For example, the semiconductor device stack structure 10 may further include a connection terminal 136. The connection terminal 136 is located between the pad 120 and the pad 132, and is electrically connected to the pad 120 and the pad 132, thereby bonding the semiconductor device structure 100A and the semiconductor device structure 122 to each other. In some embodiments, the connection terminal 136 may be a bump (for example, solder ball), but the disclosure is not limited thereto.

Based on the above embodiments, it can be known that in the semiconductor device stack structure 10, the through-substrate vias 110 pass through the substrate 102. Each through-substrate via 110 is located directly below the corresponding semiconductor device 104. Each through-substrate via 110 is electrically connected to the corresponding semiconductor device 104 and the redistribution layer 106. The size of the through-substrate via 108 is greater than the size of each through-substrate via 110. That is, the through-substrate via 110 may be smaller in size. Therefore, the number of routing layers on the front side S1 of the substrate 102 and the footprint occupied by the through-substrate vias can be reduced, which increases the flexibility in controlling the warpage of the wafer/chip. In addition, power supply and/or signal transmission to the semiconductor devices 104 can be achieved by the through-substrate vias 110 and the redistribution layer 106 located on the back side S2 of the substrate 102.

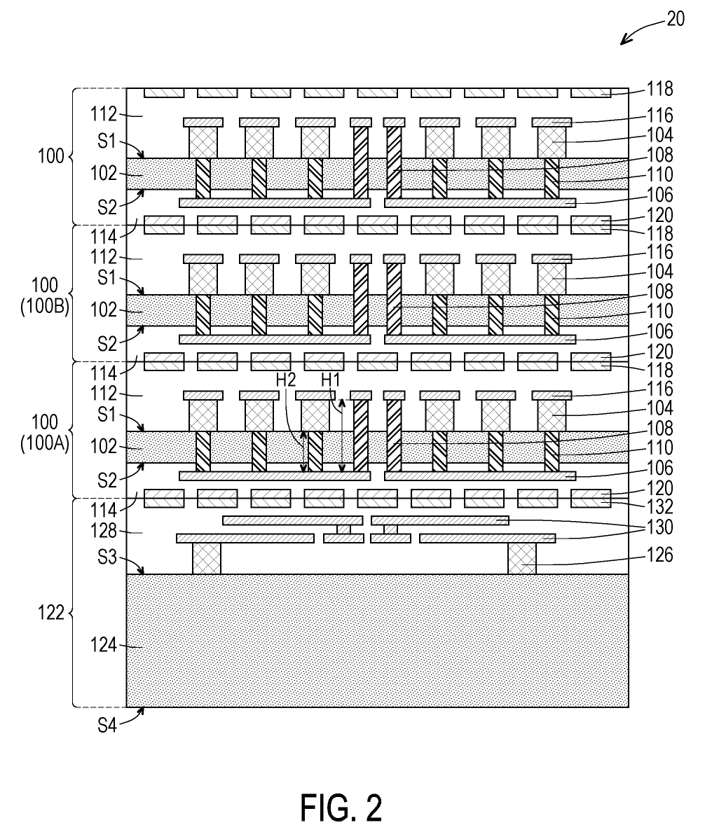

FIG. 2 is a cross-sectional view of the semiconductor device stack structure according to other embodiments of the disclosure.

Referring to FIG. 1 and FIG. 2, the differences between a semiconductor device stack structure 20 in FIG. 2 and the semiconductor device stack structure 10 in FIG. 1 are as follows. Referring to FIG. 2, the bonding method for bonding two adjacent semiconductor device structures 100 (for example, semiconductor device structure 100A and semiconductor device structure 100B) in the semiconductor device stack structure 20 may be hybrid bonding. In the semiconductor device stack structure 20, the pads 118 and the pads 120 may serve as bonding pads. For example, in the semiconductor device stack structure 20, the pads 118 of the semiconductor device structure 100A may be bonded to the pads 120 of the semiconductor device structure 100B, and the dielectric structure 112 of the semiconductor device structure 100A may be bonded to the dielectric structure 114 of the semiconductor device structure 100B, thereby bonding the semiconductor device structure 100A and the semiconductor device structure 100B to each other. In the semiconductor device stack structure 20, the materials of the pad 118 and the pad 120 used for hybrid bonding are, for example, copper, tantalum, tantalum nitride, or a combination thereof.

The bonding method for bonding the semiconductor device structure 100A and the semiconductor device structure 122 in the semiconductor device stack structure 20 may be hybrid bonding. In the semiconductor device stack structure 20, the pads 120 and the pads 132 may serve as bonding pads. For example, in the semiconductor device stack structure 20, the pads 120 of the semiconductor device structure 100A may be bonded to the pads 132 of the semiconductor device structure 122, and the dielectric structure 114 of the semiconductor device structure 100A may be bonded to the dielectric structure 128 of the semiconductor device structure 122, thereby bonding the semiconductor device structure 100A and the semiconductor device structure 122 to each other. In the semiconductor device stack structure 20, the materials of the pad 120 and the pad 132 used for hybrid bonding are, for example, copper, tantalum, tantalum nitride, or a combination thereof.

Furthermore, in the semiconductor device stack structure 10 in FIG. 1 and the semiconductor device stack structure 20 in FIG. 2, identical or similar components are denoted by the same reference numerals, and the descriptions thereof will be omitted.

Based on the above embodiments, it can be known that in the semiconductor device stack structure 20, the through-substrate vias 110 pass through the substrate 102. Each through-substrate via 110 is located directly below the corresponding semiconductor device 104. Each through-substrate via 110 is electrically connected to the corresponding semiconductor device 104 and the redistribution layer 106. The size of the through-substrate via 108 is greater than the size of each through-substrate via 110. That is, the through-substrate via 110 may be smaller in size. Therefore, the number of routing layers on the front side S1 of the substrate 102 and the footprint occupied by the through-substrate vias can be reduced, which increases the flexibility in controlling the warpage of the wafer/chip. In addition, power supply and/or signal transmission to the semiconductor devices 104 can be achieved by the through-substrate vias 110 and the redistribution layer 106 located on the back side S2 of the substrate 102.

In summary, the semiconductor device stack structure according to the above embodiments includes multiple first semiconductor device structures arranged in a stack. Each first semiconductor device structure includes a substrate, multiple semiconductor devices, a redistribution layer, a first through-substrate via, and multiple second through-substrate vias. The substrate has a front side and a back side. The semiconductor devices are located on the front side of the substrate. The redistribution layer is located on the back side of the substrate. The first through-substrate via passes through the substrate. The first through-substrate via is electrically connected to the redistribution layer. The second through-substrate vias pass through the substrate. Each second through-substrate via is located directly below the corresponding semiconductor device. Each second through-substrate via is electrically connected to the corresponding semiconductor device and the redistribution layer. The size of the first through-substrate via is greater than the size of each second through-substrate via. That is, the second through-substrate via may be smaller in size. Therefore, the number of routing layers on the front side of the substrate and the footprint occupied by the through-substrate vias can be reduced, which increases the flexibility in controlling the warpage of the wafer/chip. In addition, power supply and/or signal transmission to the semiconductor devices can be achieved by the second through-substrate vias and the redistribution layer located on the back side of the substrate.

Although the disclosure has been described with reference to the above embodiments, they are not intended to limit the disclosure. Any person having ordinary knowledge in the art may make modifications and changes without departing from the spirit and scope of the disclosure. Therefore, the scope of protection of the disclosure shall be defined by the appended claims.

What is claimed is:

1. A semiconductor device stack structure, comprising:
a plurality of first semiconductor device structures arranged in a stack, wherein each of the plurality of first semiconductor device structures comprises:
a substrate having a front side and a back side;
a plurality of semiconductor devices located on the front side of the substrate;
a redistribution layer located on the back side of the substrate;
a first through-substrate via passing through the substrate and electrically connected to the redistribution layer; and
a plurality of second through-substrate vias passing through the substrate, wherein each of the plurality of second through-substrate vias is located directly below a corresponding one of the plurality of semiconductor devices and electrically connected to the corresponding one of the plurality of semiconductor devices and the redistribution layer,
wherein a size of the first through-substrate via is greater than a size of each of the plurality of second through-substrate vias.

2. The semiconductor device stack structure according to claim 1, wherein the plurality of first semiconductor device structures comprise a plurality of semiconductor wafers.

3. The semiconductor device stack structure according to claim 1, wherein the plurality of first semiconductor device structures comprise a plurality of semiconductor chips.

4. The semiconductor device stack structure according to claim 1, wherein the first through-substrate via is not located directly below the plurality of semiconductor devices.

5. The semiconductor device stack structure according to claim 1, wherein an overall height of the first through-substrate via is greater than an overall height of each of the plurality of second through-substrate vias.

6. The semiconductor device stack structure according to claim 1, wherein a volume of the first through-substrate via is greater than a volume of each of the plurality of second through-substrate vias.

7. The semiconductor device stack structure according to claim 1, wherein a volume of the first through-substrate via is 10 times to 1000 times a volume of each of the plurality of second through-substrate vias.

8. The semiconductor device stack structure according to claim 1, wherein each of the plurality of first semiconductor device structures further comprises:
a dielectric structure located on the front side of the substrate, wherein the plurality of semiconductor devices are located in the dielectric structure.

9. The semiconductor device stack structure according to claim 8, wherein the first through-substrate via extends into the dielectric structure.

10. The semiconductor device stack structure according to claim 1, wherein each of the plurality of first semiconductor device structures further comprises:
a dielectric structure located on the back side of the substrate, wherein the redistribution layer is located in the dielectric structure.

11. The semiconductor device stack structure according to claim 10, wherein the first through-substrate via and the plurality of second through-substrate vias extend into the dielectric structure.

12. The semiconductor device stack structure according to claim 1, wherein adjacent two of the plurality of first semiconductor device structures are bonded to each other.

13. The semiconductor device stack structure according to claim 12, wherein a bonding method for bonding adjacent two of the plurality of first semiconductor device structures comprises bump bonding.

14. The semiconductor device stack structure according to claim 12, wherein a bonding method for bonding adjacent two of the plurality of first semiconductor device structures comprises hybrid bonding.

15. The semiconductor device stack structure according to claim 1, comprising a plurality of the first through-substrate vias and a plurality of the redistribution layers, wherein each of the plurality of first through-substrate vias is electrically connected to a corresponding one of the plurality of redistribution layers.

16. The semiconductor device stack structure according to claim 15, wherein the plurality of first through-substrate vias are located between the plurality of second through-substrate vias.

17. The semiconductor device stack structure according to claim 1, further comprising:
a second semiconductor device structure, wherein the plurality of first semiconductor device structures are stacked on the second semiconductor device structure.

18. The semiconductor device stack structure according to claim 17, wherein the second semiconductor device structure comprises a semiconductor wafer.

19. The semiconductor device stack structure according to claim 17, wherein the second semiconductor device structure comprises a semiconductor chip.

20. The semiconductor device stack structure according to claim 17, wherein one of the plurality of first semiconductor device structures that is closest to the second semiconductor device structure is bonded to the second semiconductor device structure.
